(19) United States
(12) Patent Application Publication
(10) Pub. No.: US 2006/0223267 A1
(43) Pub. Date: Oct. 5, 2006

(54) Method of production of charge-trapping memory devices

(76) Inventors: Stefan Machill, Dresden (DE); Christoph Ludwig, Langebruck (DE); Jan-Malte Schley, Dresden (DE); Gunther Wein, Nittendorf (DE); Jens-Uwe Sachse, Dresden (DE); Mathias Krause, Dresden (DE); Mark Isler, Dresden (DE); Joachim Deppe, Dresden (DE)

Correspondence Address: SLATER & MATSIL LLP, 17950 PRESTON ROAD, SUITE 1000, DALLAS, TX, 75252, US

(21) Appl. No.: 11/095,925

(22) Filed: Mar. 31, 2005

(51) Int. Cl. H01L 21/336

(52) U.S. Cl. 438/288; 438/303; 438/954

(57) ABSTRACT

The surfaces of wordline stacks and intermediate areas of a main substrate surface are covered with an oxynitride liner. Either sidewall spacers of BPSG are formed or a further liner of nitride is deposited and spacers of oxide are formed. These spacers are used in a peripheral area of addressing circuitry to implant doped source/drain regions. The oxynitride reduces the stress between the nitride and the semiconductor material and prevents charge carriers from penetrating out of a memory layer of nitride into the liner.

### TECHNICAL FIELD

This invention relates to a method for the production of memory devices, which comprise an array of charge-trapping memory cells and an addressing logic circuitry in a peripheral area.

### BACKGROUND

Nonvolatile memory cells that are electrically programmable and erasable can be realized as charge-trapping memory cells, which comprise a memory layer sequence of dielectric materials with a memory layer between confinement layers of dielectric material having a larger energy band gap than the memory layer. The memory layer sequence is arranged between a channel region within a semiconductor body and a gate electrode provided to control the channel by means of an applied electric voltage. Examples of charge-trapping memory cells are the SONOS memory cells, in which each confinement layer is an oxide and the memory layer is a nitride of the semiconductor material, usually silicon (see, e.g., U.S. Pat. No. 5,768,192, and U.S. Pat. No. 6,011,725, which are both incorporated herein by reference).

Charge carriers are accelerated from source to drain through the channel region and gain enough energy to be able to penetrate the lower confinement layer and to be trapped within the memory layer. The trapped charge carriers change the threshold voltage of the cell transistor structure. Different programming states can be read by applying the appropriate reading voltages.

A publication by B. Eitan et al., “NROM: a Novel Localized Trapping, 2-Bit Nonvolatile Memory Cell” in IEEE Electron Device Letters, volume 21, pages 543 to 545 (2000), which is incorporated herein by reference, describes a charge-trapping memory cell with a memory layer sequence of oxide, nitride and oxide that is especially adapted to be operated with a reading voltage that is reverse to the programming voltage (reverse read). The oxide-nitride-oxide layer sequence is especially designed to avoid the direct tunneling regime and to guarantee the vertical retention of the trapped charge carriers. The oxide layers are specified to have a thickness of more than 5 nm.

The memory layer can be substituted with another dielectric material, provided the energy band gap is smaller than the energy band gap of the confinement layers. The difference in the energy band gaps should be as great as possible to secure a good charge carrier confinement and thus a good data retention. When using silicon dioxide as confinement layers, the memory layer may be tantalum oxide, cadmium silicate, titanium oxide, zirconium oxide or aluminum oxide. Also intrinsically conducting (non-doped) silicon may be used as the material of the memory layer.

A semiconductor memory device comprises an array of memory cells provided for the storage of information and an addressing circuitry that is located in a peripheral area. CMOS field-effect transistors are important logic components of the addressing circuits. Source and drain regions of these field-effect transistors are arranged at a certain distance from the gate electrodes. In the production process, therefore, sidewall spacers at flanks of the gate electrode stacks are used to implant the source/drain regions so that the pn junctions between the doped regions and the basic semiconductor material are located at a distance from the gate electrode. To this end, a nitride liner is deposited on the surfaces of the substrate or semiconductor body and the gate electrode stacks. This liner protects the areas of shallow trench isolations between the devices and serves as an etching stop layer for the RIE (reactive iron etching) of the oxide spacers. After the implantations of the source/drain regions have taken place, the oxide spacers are removed, usually by means of wet chemical etching. The oxide spacers are preferably formed as TEOS (tetraethylorthosilicate) spacers, and the oxide is applied directly onto the nitride liner. The oxide can be removed selectively to the nitride of the liner. Therefore, the nitride liner is suitable as an etching stop layer in this production step.

However, a nitride liner that is applied all over the surface of the device and thus covers also the area of the memory cell array shows negative effects on the performance of the memory cell transistors. The nitride liner is directly adjacent to the wordline stack of the memory cells and is in contact with the memory layer sequence, which is usually oxide/nitride/oxide. This is supposed to cause poor values of retention after cycling (RAC), which is one of the key parameters to be optimized in a charge-trapping memory device. Insufficient RAC values are probably related to a high trapping density of charge carriers in the nitride liner and/or to high mechanical stress caused by the nitride liner being deposited directly on the memory layer sequence so that a formation of leakage paths in the memory layer sequence may result.

### SUMMARY OF THE INVENTION

In one aspect, the present invention provides a charge-trapping memory device with improved retention after cycling values, especially an NROM cell comprising an oxide-nitride-oxide memory layer sequence.

In a further aspect, this invention removes the difficulties deriving from the application of a nitride liner adjacent to the memory layer sequence.

The preferred embodiment makes use of an oxynitride liner instead of the usual nitride liner. This reduces the stress between the liner and the semiconductor material underneath. A leakage of charge carriers from the memory layer sequence into the liner is inhibited.

The sidewall spacers that are used in the peripheral area to form source/drain regions having junctions at a distance from the gate electrode are formed of boron phosphorous silicate glass (BPSG). Instead, the spacers can be formed of oxide, especially an oxide from a TEOS (tetraethylorthosilicate) precursor, if the oxynitride liner is doubled with a nitride liner, which functions as an etching stop layer in the formation of the oxide spacer.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a cross section of an intermediate product after the implantation of source/drain regions in the memory cell array;

FIG. 2 shows a cross section according to FIG. 1 after the application of the oxynitride liner;

FIG. 3 shows a cross section according to FIG. 2 after the application of the conformal layer of spacer material;

FIG. 4 shows a cross section according to FIG. 3 after the etching of sidewall spacers and the introduction of dielectric material;

FIG. 5 shows a cross section according to FIG. 4 in the peripheral area;

FIG. 6 shows a cross section according to FIG. 5 after the implantation of source/drain regions in the peripheral area;

FIG. 7 shows a cross section according to FIG. 6 after the application of the dielectric material;

FIG. 8 shows a cross section according to FIG. 7 of an alternative embodiment;

FIG. 9 shows a cross section according to FIGS. 7 and 8 after the planarization of the dielectric material;

FIG. 10 shows a cross section according to FIG. 2 of an alternative embodiment that comprises two liners;

FIG. 11 shows a cross section according to FIG. 10 after the process steps according to FIG. 4;

FIG. 12 shows a cross section according to FIG. 11 in the peripheral area; and

FIG. 13 shows a cross section according to FIG. 12 after the application and planarization of the dielectric material.

The following list of reference symbols can be used in conjunction with the figures:

| | | | |
|---|---|---|---|
| 1 | substrate | 7 | sidewall insulation |
| 2 | source/drain region | 8 | top insulation |
| 3 | memory layer sequence | 9 | oxide layer |
| 31 | lower boundary layer | 10 | oxynitride liner |
| 32 | memory layer | 11 | nitride liner |
| 33 | upper boundary layer | 12 | conformal layer |
| 4 | wordline stack | 13 | sidewall spacer |
| 5 | gate dielectric | 14 | dielectric material |
| 6 | gate electrode | | |

### DETAILED DESCRIPTION OF ILLUSTRATIVE EMBODIMENTS

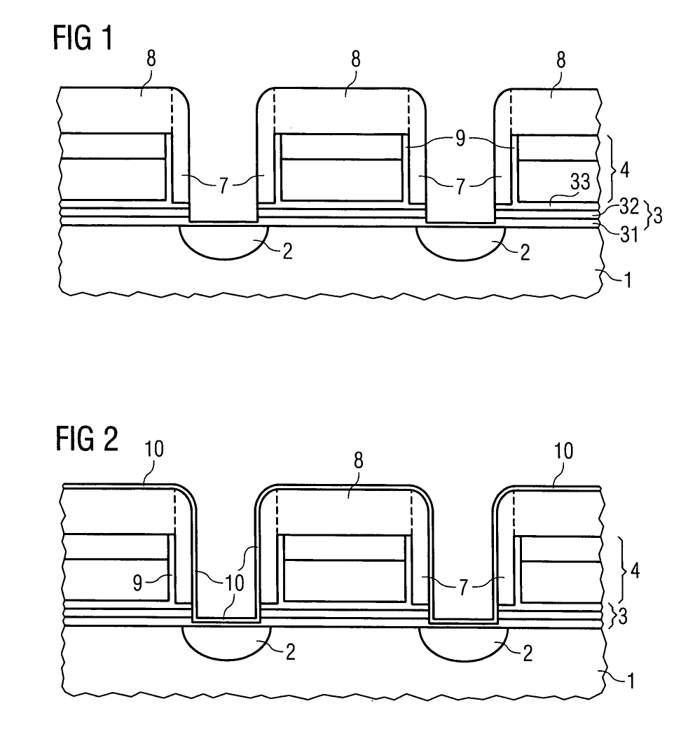

FIG. 1 shows a cross section of an intermediate product of the preferred embodiment. It is a section of the memory cell array that is arranged at a main surface of a semiconductor body 1, such as a substrate or other layer or region. This main surface comprises source/drain regions 2, a memory layer sequence 3, which includes a lower boundary layer 31, a memory layer 32 and an upper boundary layer 33, and wordline stacks 4 with sidewall insulations 7 in spacer form, top insulations 8 and an optional oxide layer 9 covering the sidewalls of the electrically conductive wordline layers. The lower boundary layer 31 and the upper boundary layer 33 can be oxide, while the memory layer 32 can be nitride. In other embodiments, other materials can be used. The sidewall insulations 7 and the top insulations 8 of the wordline stacks 4 can also be nitride. The memory layer sequence 3 has almost completely been removed in the areas above the source/drain regions 2, but could have been left there also.

FIG. 2 shows how the surfaces of the structure according to FIG. 1 are covered by an oxynitride liner 10. In the embodiment shown in the figures, only a partial layer of the lower boundary layer 31 is maintained between the wordline stacks above the semiconductor material of the source/drain regions 2. Therefore, the oxynitride liner 10 is located at a small distance from the semiconductor material 1 and immediately adjacent to the memory layer 32. The oxynitride material has considerable advantage over the heretofore used nitride liners.

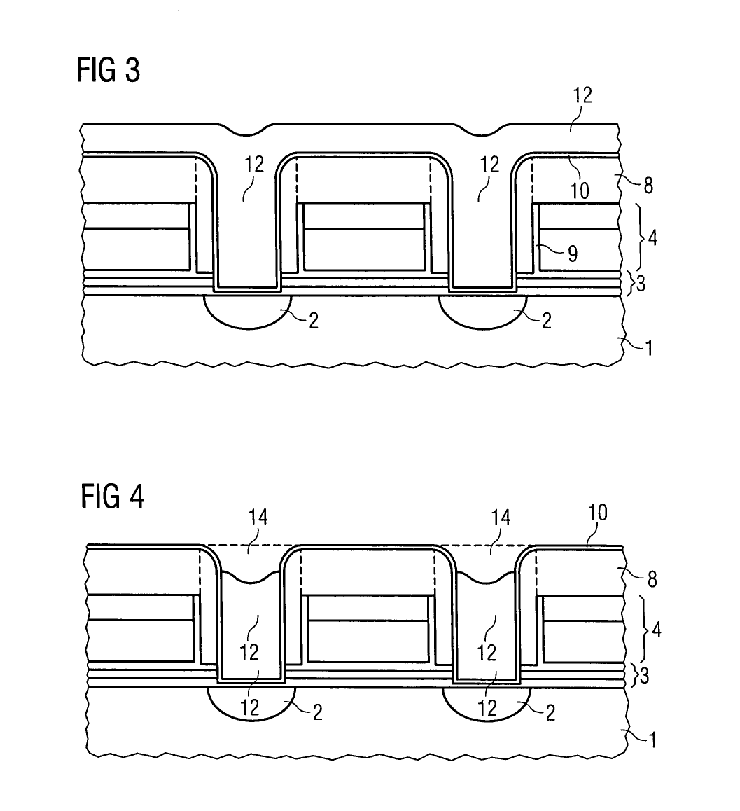

FIG. 3 shows a cross section according to FIG. 2 after the application of a conformal layer 12 of the spacer material. In this variant of the inventive method, this conformal layer 12 is boron phosphorus silicate glass (BPSG). The BPSG is etched selectively to the oxynitride of the liner 10. This is shown in the next figure.

FIG. 4 shows the cross section according to FIG. 3 after the etching of the conformal layer 12, which can be effected by RIE (reactive ion etching) and is performed anisotropically, according to a standard method to form sidewall spacers. In the area of the memory cell array, the wordline stacks are arranged at such small distances that the remaining parts of the conformal layer 12 do not form separate sidewall spacers, but completely fill at least the lower volumes of the interspaces between the wordline stacks, as can be seen from FIG. 4. The open volume above the remaining parts of the spacer material is filled with dielectric material 14, which is planarized to form a plain surface with the upper surface of the wordline stacks.

FIG. 5 shows the cross section in the peripheral area, where transistor structures of the addressing circuit are provided with a layer of a gate dielectric 5. The gate electrode 6, preferably electrically conductive doped polysilicon, and an appertaining conductor track can be structured similarly to the wordline stacks and can especially be provided with a metal or metal silicide layer to reduce the track resistance. Sidewall insulations 7 and top insulations 8 can be provided in a similar manner as in the memory cell array.

FIG. 5 clearly shows that the distance between the gate electrodes is larger in the peripheral area than in the area of the memory cell array. Therefore, the anisotropic etching of the conformal layer 12 results in sidewall spacers 13 at the flanks of the gate electrode stacks of the transistor devices in the addressing periphery. The spacers 13 can be formed with variable height, either flush with the top surface of the gate electrode stacks or, as indicated by the dashed lines in FIG. 5, somewhat recessed into the interspace between the gate electrode stacks.

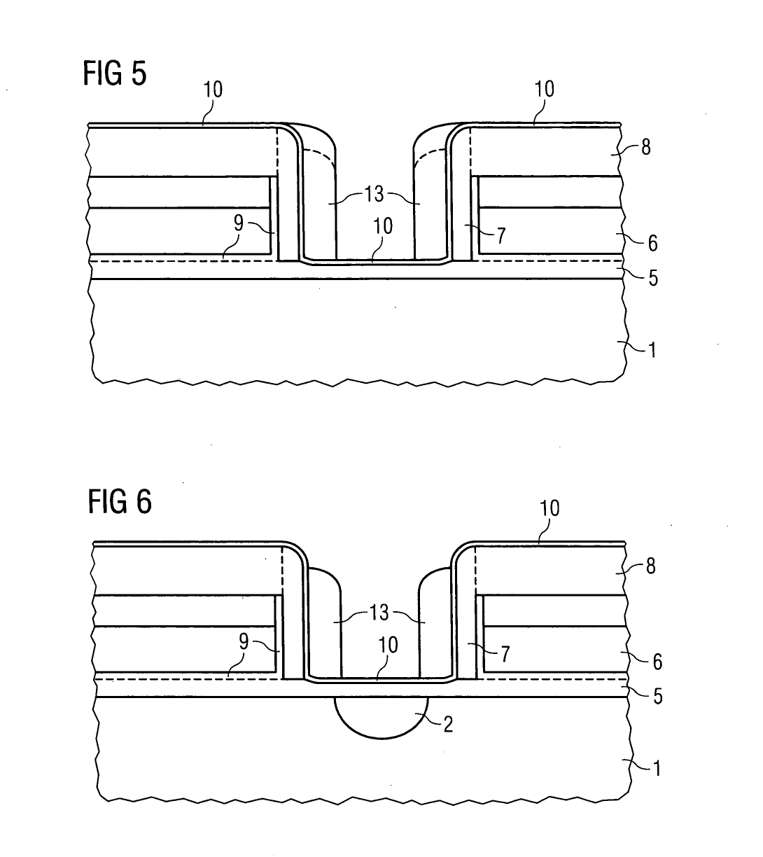

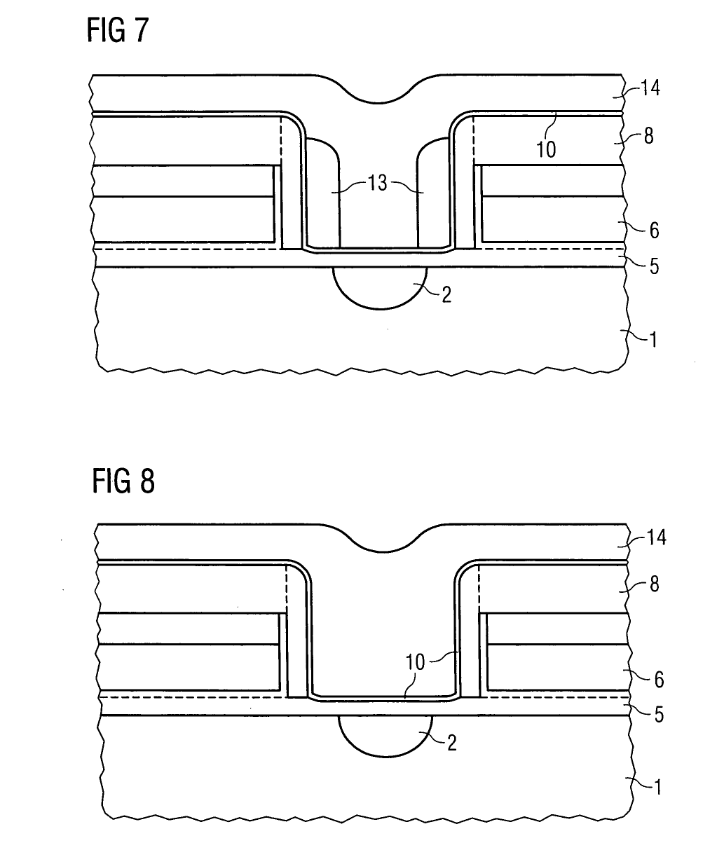

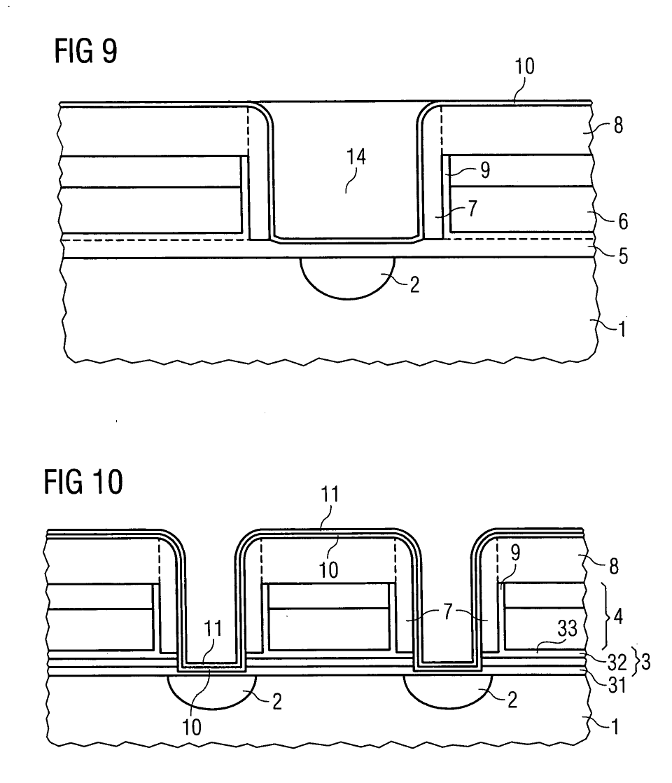

FIG. 6 shows the cross section according to FIG. 5 after the implantation of a dopant to form the source/drain regions 2. Then the dielectric material 14 is deposited to fill the openings between the gate electrode stacks, as shown in FIG. 7. This dielectric material can be BPSG so that a homogenous filling of the interspaces between the stacks is obtained according to the cross section of FIG. 8. The sidewall spacers 13 can instead be removed before the deposition of the dielectric material 14. This makes no significant difference, since the oxynitride liner 10 is still present on the surfaces and can be used as an etching stop layer in the removal of the sidewall spacers. The dielectric material 14 is planarized to obtain the plain surface shown in FIG. 9.

FIG. 10 shows a cross section in the region of the memory cell array according to the cross section of FIG. 2 after the application of the oxynitride liner 10 and a nitride liner 11 doubling the oxynitride liner 10. This alternative method is intended for the use of oxide spacers, especially of TEOS spacers (e.g., spacers formed by the decomposition of tetraethylorthosilicate. Therefore, the oxynitride liner 10 is covered with a nitride liner 11, which is applied to the upper surface of the oxynitride liner 10. Here again the oxynitride reduces or prevents stress between the nitride and the semiconductor material and prevents charge carriers that are trapped in the memory layer from leaking into the nitride liner. The further process steps already described are subsequently performed in principally the same way, but with the difference that the material provided for the sidewall spacers 13 can be an oxide. The oxide is preferably formed by means of TEOS in a usual process that is known. It is anisotropically etched back to form the sidewall spacers 13 in the peripheral area.

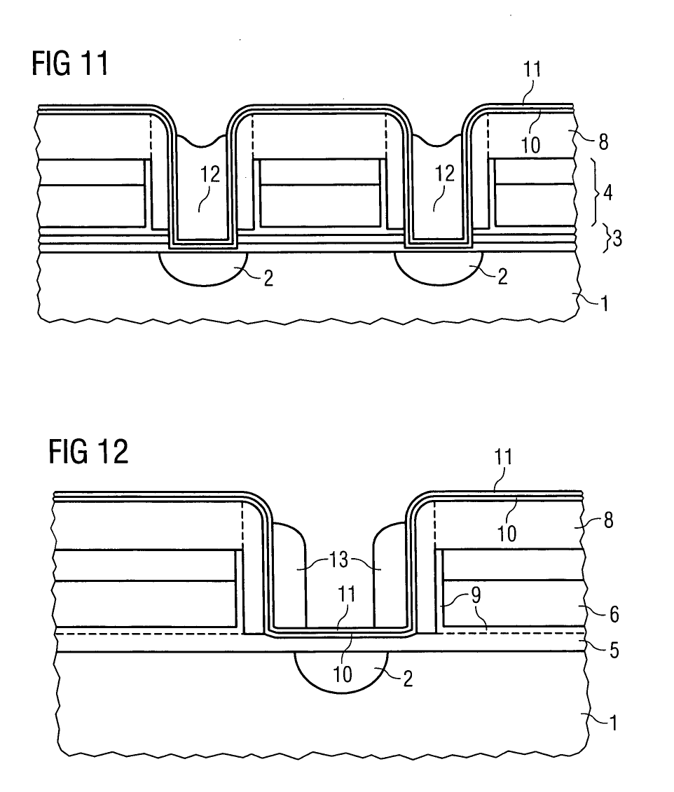

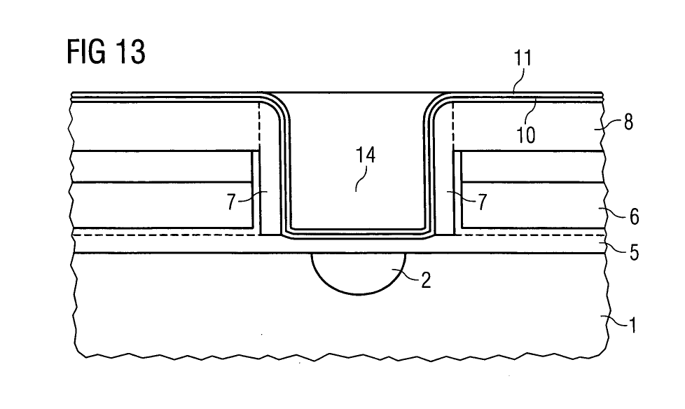

FIG. 11 shows a cross section according to FIG. 10 after the etching of the conformal layer 12 of spacer material. FIG. 12 shows the structure thus obtained in the peripheral area, where the sidewall spacers 13 of oxide are arranged above the double layer of the oxynitride liner 10 and the nitride liner 11. The sidewall spacers 13 are used to mask the implantation of doping atoms to form doped regions of source and drain. The cross section of FIG. 13 corresponds to the cross section of FIG. 9, and shows the structure of the peripheral area after the removal of the sidewall spacers 13 and the subsequent deposition and planarization of the dielectric material 14, which can be BPSG. The difference between the described preferred embodiments is to be seen in the presence or not of the additional nitride liner 11.

Although the present invention and its advantages have been described in detail, it should be understood that various changes, substitutions and alterations can be made herein without departing from the spirit and scope of the invention as defined by the appended claims.

What is claimed is:

1. A method for producing a charge-trapping memory device, the method comprising:
providing a semiconductor body having a main surface;
applying a memory layer sequence of dielectric materials provided for charge-trapping;
forming wordline stacks in an area of an array of memory cells and gate electrodes in the peripheral area of an addressing circuitry;
implanting source/drain regions in said area of said memory cells self-aligned to said wordline stacks;
applying an oxynitride liner;
forming sidewall spacers in said peripheral area;
implanting source/drain regions in said peripheral areas using said sidewall spacers as masks; and
filling interspaces between said wordline stacks and said gate electrodes with a dielectric material.

2. The method according to claim 1, wherein forming sidewall spacers comprises forming said sidewall spacers of a material that is etched selectively to oxynitride.

3. The method according to claim 2, wherein forming sidewall spacers comprises forming said sidewall spacers of boron phosphorus silicate glass.

4. The method according to claim 1, further comprising applying a nitride liner onto said oxynitride liner.

5. The method according to claim 4, wherein forming sidewall spacers comprises forming said sidewall spacers of oxide.

6. The method according to claim 5, wherein forming sidewall spacers comprises forming said sidewall spacers using TEOS.

7. The method according to claim 1, wherein providing a semiconductor body comprises providing a semiconductor substrate.

8. The method according to claim 1, wherein the memory layer sequence comprises an oxide-nitride-oxide layer sequence.

9. The method according to claim 1, wherein filling interspaces between said gate electrodes further comprises filling interspaces between said wordline stacks.

10. The method according to claim 1, further comprising removing the sidewall spacers subsequent to implanting source/drain regions but prior to filling interspaces between said gate electrodes.

11. The method according to claim 10, wherein filling interspaces between said gate electrodes further comprises filling interspaces between said wordline stacks.

12. The method according to claim 1, wherein forming sidewall spacers comprises filling interspaces between said wordline stacks.

13. The method according to claim 1, wherein forming wordline stacks comprises forming wordline stacks over portions of the memory layer sequence and wherein forming gate electrodes comprises forming gate electrodes over portions of a gate dielectric layer.

14. A method for producing a charge-trapping memory device, the method comprising:
providing a semiconductor body;
forming a memory layer sequence adjacent the semiconductor body, the memory layer sequence including dielectric materials provided for charge-trapping;
forming a gate dielectric adjacent the semiconductor body;
forming wordline stacks adjacent the memory layer sequence in a memory array area and forming gate electrodes adjacent the gate dielectric in the peripheral area of an addressing circuitry;
implanting source/drain regions in said memory array area self-aligned to said wordline stacks;
applying an oxynitride liner over the peripheral area and the memory array area;
forming sidewall spacers along sidewalls of the gate electrodes in said peripheral area and filling interspaces between the wordline stacks in the area of the array of memory cells;
implanting source/drain regions in said peripheral area using said sidewall spacers as masks in the memory array area; and
filling interspaces between said gate electrodes with a dielectric material.

15. The method of claim 14, further comprising removing the sidewall spacers after implanting source/drain regions in the peripheral area, wherein filling interspaces between said gate electrodes further comprises filling interspaces between said wordline stacks.

16. The method of claim 14, wherein forming sidewall spacers comprises forming BPSG spacers.

17. The method of claim 14, wherein forming sidewall spacers comprises forming oxide spacers using a TEOS precursor.

18. The method of claim 17, further comprising forming a nitride liner over the oxynitride liner.

19. The method of claim 14 wherein forming a memory layer sequence comprises forming a memory layer sequence over and physically touching a planar portion of the semiconductor body and wherein forming wordline stacks comprises forming wordline stacks over the memory layer sequence such that a conductive layer of the wordline stacks lies parallel to an upper surface of the semiconductor body.

20. The method according to claim 14, wherein the memory layer sequence comprises an oxide-nitride-oxide layer sequence.
